(19) United States
(12) Patent Application Publication
(10) Pub. No.: US 2014/0217440 A1
(43) Pub. Date: Aug. 7, 2014

(54) LIGHT-EMITTING MODULE AND MANUFACTURING METHOD THEREOF

(71) Applicant: Lextar Electronics Corporation, Hsinchu (TW)

(72) Inventor: Chia-Ming SUNG, Hsinchu County (TW)

(73) Assignee: Lextar Electronics Corporation, Hsinchu (TW)

(21) Appl. No.: 13/902,955

(22) Filed: May 27, 2013

(30) Foreign Application Priority Data
Feb. 5, 2013 (TW) 102104416

(51) Int. Cl. H01L 33/60

(52) U.S. Cl. CPC H01L 33/60
USPC 257/98; 438/27

(57) ABSTRACT

A light-emitting module includes a first conductive lead frame, a second conductive lead frame physically separated from the first conductive lead frame, a protective plastic layer, a reflective plastic layer, and a light-emitting die. The protective plastic layer surrounds the first and second conductive lead frames, and an accommodating space s defined by the protective plastic layer, and the first and second conductive lead frames. Inner surfaces of the first and second conductive lead frames are exposed through the accommodating space. The accommodating space further includes a die-mounting region. The reflective plastic layer is formed on the inner surfaces within the accommodating space. The light-emitting die is located on the die-mounting region and is electrically connected to the first and second conductive lead frames. The light-emitting die protrudes from the reflective plastic layer.

### RELATED APPLICATIONS

This application claims priority to Taiwan Application Serial Number 102104416, filed Feb. 5, 2013, which is herein incorporated by reference.

### BACKGROUND

1. Technical Field

The present disclosure relates to a light-emitting module and manufacturing method thereof.

2. Description of Related Art

Light-emitting diodes (LEDs) are semiconductor elements, and are associated with the advantages of long lifespan, low energy consumption, small size, good shock resistance, and the ability to be used in a wide range of applications. With the development of science and technology, LEDs are not only used in indicator lights of electronic devices, but also are used in thin profile televisions, computer monitors, and lighting apparatuses.

In order to improve the light-emitting efficiency of a conventional LED package, a lead frame for supporting an LED may be plated with a silver layer having a high reflection rate, such that light emitted from the LED can be reflected by the silver layer on a surface of the lead frame. However; the silver layer is easily reacted with sulfur in the air to form black silver sulfide. Moreover, the silver layer is often formed by electrochemical processes, such that other metal particle residue is easily left remaining on the silver layer. When the LED package is in lighted, wet, and hot conditions, the properties of these metal particles may be changed, such that the silver layer yellows or blackens (e.g., undergoes oxidation).

After the LED package is used for a length of time, the reflection rate of the silver layer on the surface of the lead frame may be reduced as a result of becoming black, thereby degrading the brightness of the LED package.

### SUMMARY

An aspect of the present invention is to provide a light-emitting module.

According to an embodiment of the present invention, a light-emitting module includes a first conductive lead frame, a second conductive lead frame physically separated from the first conductive lead frame, a protective plastic layer, a reflective plastic layer, and a light-emitting die. The protective plastic layer surrounds the first and second conductive lead frames, and an accommodating space is defined by the protective plastic layer, and the first and second conductive lead frames. Inner surfaces of the first and second conductive lead frames are exposed through the accommodating space. The accommodating space further includes a die-mounting region. The reflective plastic layer is formed on the inner surfaces within the accommodating space. The light-emitting die is located on the die-mounting region and is electrically connected to the first and second conductive lead frames. The light-emitting die protrudes from the reflective plastic layer.

In an embodiment of the present invention, each of the inner surfaces of the first and second conductive lead frames includes a bottom surface and a side surface, and an obtuse angle is formed between the bottom surface and the side surface.

In an embodiment of the present invention, the die-mounting region is on the bottom surface of the inner surface of one of the first and second conductive lead frames, and a thickness of the reflective plastic layer on the bottom surface is smaller than a thickness of the light-emitting die.

In an embodiment of the present invention, the obtuse angle is in a range from 100 to 170 degrees

In an embodiment of the present invention, the light-emitting die has at least two conductive wires, and the two conductive wires are respectively electrically connected to the first and second conductive lead frames by solder, and a melting point temperature of the reflective plastic layer is lower than a melting point temperature of the solder.

In an embodiment of the present invention, a melting point temperature of the protective plastic layer is higher than the melting point temperature of the solder.

In an embodiment of the present invention the light-emitting module further includes a packaging adhesive. The packaging adhesive is located in the accommodating space and covers the reflective plastic layer and the light-emitting die.

In an embodiment of the present invention, the packaging adhesive includes fluorescent powders fore changing a wavelength of a light of the light-emitting die.

In an embodiment of the present invention, the reflective plastic layer is made of a thermoplastic material that is selected from for example, the group consisting of polycarbonate (PC), polyethylene (PET), polyester (PE), polybutylene terephthalate (PBT), polycycolhexaylene terephthalate (PCT), polypropene (PP), and nylon.

In an embodiment of the present invention, the protective plastic layer is made of a thermoplastic material that is selected from, for example, the group consisting of polycarbonate, polyethylene, polyester, polybutylene terephthalate, polycycolhexaylene terephthalate, polypropene, and nylon.

An aspect of the present invention is to provide a manufacturing method of a light-emitting module.

According to an embodiment of the present invention, a manufacturing method of a light-emitting module includes a number of steps. (a) A first conductive lead frame and a second conductive lead frame physically separated from the first conductive lead frame are provided. (b) A protective plastic layer is formed by injection molding for surrounding the first and second conductive lead frames. An accommodating space is defined by the protective plastic layer, and the first and second conductive lead frames. Inner surfaces of the first and second conductive lead frames are exposed through the accommodating space, and the accommodating space includes a die-mounting region. (c) A reflective plastic block is formed on a side surface of the inner surfaces of the first and second conductive lead frames within the accommodating space. (d) A light-emitting die is mounted on the die-mounting region. (e) A baking treatment process is applied to melt the reflective plastic block to form a reflective plastic layer, and the reflective plastic layer covers the inner surfaces of the first and second conductive lead frames.

In an embodiment of the present invention, step (d) further includes performing a soldering process, such that the light-emitting die is electrically connected to the first and second conductive lead frames.

In an embodiment of the present invention, step (e) is performed in a reflow oven or in a bake chamber.

In an embodiment of the present invention a temperature of the baking treatment process is in a range from 245 to 260° C., a melting point temperature of the protective plastic layer is higher than 260° C., and a melting point temperature of the reflective plastic layer is lower than 245° C.

In an embodiment of the present invention, the manufacturing method of the light-emitting module further includes filling a packaging adhesive in the accommodating space for covering the reflective plastic layer and the light-emitting die.

In an embodiment of the present invention, the packaging adhesive comprises fluorescent powders for changing a wavelength of a light of the light-emitting die.

In an embodiment of the present invention, the reflective plastic layer is made of a thermoplastic material that is selected from, for example, the group consisting of polycarbonate (PC), polyethylene (PET), polyester (PE), polybutylene terephthalate (PBT), polycycolhexaylene terephthalate (PCT), polypropene (PP), and nylon.

In an embodiment of the present invention, the protective plastic layer is made of a thermoplastic material that is selected from, for example, the group consisting of polycarbonate, polyethylene, polyester, polybutylene terephthalate, polycycolhexaylene terephthalate, polypropene, and nylon.

In the aforementioned embodiments of the present invention, the protective plastic layer is on the outer surfaces of the first and second conductive lead frames, and the reflective plastic layer is on the inner surfaces of the first and second conductive lead frames. When the light-emitting die located on the die-mounting region emits light, the light of the light-emitting die can be reflected by the reflective plastic layer. Since the reflective plastic layer is made of a nonmetallic material, the reflective plastic layer does not undergo yellowing, vulcanization, and oxidation as in the case of a conventional silver reflective layer. Furthermore, the reflective plastic layer can fill a gap between the first and second conductive lead frames, such that a solder flux does not permeate into the gap. Therefore, the reflective plastic layer can prevent shorting between the first and second conductive lead frames.

During the manufacture of the light-emitting module, the reflective plastic block can be formed on the side surfaces of the inner surfaces of the first and second conductive lead frames, after which the reflective plastic block is melted by the baking treatment process. As a result, the melted reflective plastic layer flows along the inner surfaces of the first and second conductive lead frames by gravity. After the reflective plastic layer is solidified, the reflective plastic layer can cover the inner surfaces of the first and second conductive lead frames

### BRIEF DESCRIPTION OF THE DRAWINGS

FIG. 1 is a cross-sectional view of a light-emitting module according to an embodiment of the present invention;

FIG. 2 is a flow chart of a manufacturing method of a light-emitting module according to an embodiment of the present invention;

FIG. 3 is a cross-sectional view of a first conductive lead frame and a second conductive lead frame shown in FIG. 1;

FIG. 4 is a cross-sectional view of the first and second conductive lead frames shown in FIG. 3 when a protective plastic layer is formed thereon;

FIG. 5 is a cross-sectional view of the first and second conductive lead frames shown in FIG. 4 when a reflective plastic block is formed thereon;

FIG. 6 is a cross-sectional view of the first and second conductive lead frames shown in FIG. 5 when a light-emitting die is mounted thereon; and

FIG. 7 is a cross-sectional view of the first and second conductive lead frames shown in Fig, 6 after the reflective plastic block is melted to cover the inner surfaces of the first and second conductive lead frames.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings,

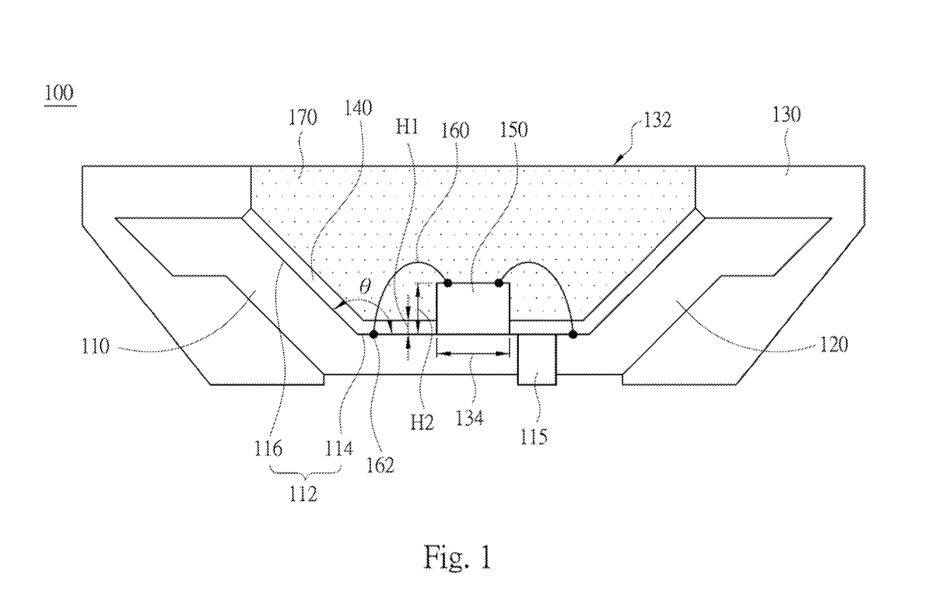

FIG. 1 is a cross-sectional view of a light-emitting module 100 according to an embodiment of the present invention. As shown in FIG. 1, the light-emitting module 100 includes a first conductive lead frame 110, a second conductive lead frame 120, a protective plastic layer 130, a reflective plastic layer 140, and a light-emitting die 150. The second conductive lead frame 120 is physically separated from the first conductive lead frame 110. For example, an insulating portion 115 can be used to insulate the first conductive lead frame 110 from the second conductive lead frame 120. The first and second conductive lead frames 110, 120 may be made of metal, and the insulating portion 115 may be made of a material that includes plastic or rubber. In addition, each of the first and second conductive lead frames 110, 120 includes an inner surface 112, and each of the inner surfaces 112 of the first and second conductive lead frames 110, 120 includes a bottom surface 114 and a side surface 116. An obtuse angle θ is formed between the bottom surface 114 and the side surface 116 of each of the inner surfaces 112 of the first and second conductive lead frames 110, 120. In this embodiment, the obtuse angle θ is in a range from 100 to 170 degrees, but the present invention is not limited to such a range.

The protective plastic layer 130 surrounds the first and second conductive lead frames 110, 120, and an accommodating space 132 is defined by the protective plastic layer 130, and the first and second conductive lead frames 110, 120. The inner surfaces 112 of the first and second conductive lead frames 110, 120 are exposed through the accommodating space 132. In this embodiment, the protective plastic layer 130 may be made of a thermoplastic material that is selected from, for example, the group consisting of polycarbonate (PC), polyethylene (PET), polyester (PE), polybutylene terephthalate (PBT), polycycolhexaylene terephthalate (PCT), polypropene (PP), and nylon, but the present invention is not limited in this regard.

The reflective plastic layer 140 is formed on the inner surfaces 112 within the accommodating space 132. In this embodiment, the reflective plastic layer 140 may be made of a thermoplastic material that is selected from, for example, the group consisting of polycarbonate, polyethylene, polyester, polybutylene terephthalate, polycycolhexaylene terephthalate, polypropene, and nylon, but the present invention is not limited in this regard.

Moreover, the accommodating space 132 further includes a die-mounting region 134. The light-emitting die 150 is located on the die-mounting region 134 and is electrically connected to the first and second conductive lead frames 110, 120. The die-mounting region 134 is on the bottom surface 114 of the inner surface 112 of the first conductive lead frame 110. The thickness H1 of the reflective plastic layer 140 on the bottom surface 114 of the inner surface 112 of the first conductive lead frame 110 is smaller than the thickness H2 of the light-emitting die 150. Therefore, the light-emitting die 150 can protrude from the reflective plastic layer 140.

In this embodiment, the light-emitting die 150 has two conductive wires 160 connected to the anode and cathode thereof, and the two conductive wires 160 are respectively electrically connected to the first and second conductive lead frames 110, 120 by solder 162. The melting point temperature of the reflective plastic layer 140 is lower than the melting point temperature of the solder 162. The melting point temperature of the protective plastic layer 130 is higher than the melting point temperature of the solder 162. For example, the melting point temperature of the reflective plastic layer 140 is lower than 245° C., the melting point temperature of the solder 162 is 260° C., and the melting point temperature of the protective plastic layer 130 is higher than 260° C.

The light-emitting module 100 may further include a packaging adhesive 170. The packaging adhesive 170 is located in the accommodating space 132 and covers the reflective plastic layer 140 and the light-emitting die 150. The packaging adhesive 170 may include fluorescent powders for changing a wavelength of the light of the light-emitting die 150.

The protective plastic layer 130 is disposed on the outer surfaces of the first and second conductive lead frames 110, 120 (i.e., surfaces outside of the accommodating space 132), and the reflective plastic layer 140 is on the inner surfaces 112 of the first and second conductive lead frames 110, 120 (i.e., surfaces within the accommodating space 132). When the light-emitting die 150 located on the die-mounting region 134 emits light, the light of the light-emitting die 150 can be reflected by the reflective plastic layer 140. Since the reflective plastic layer 140 is made of a nonmetallic material, the reflective plastic layer 140 does not undergo yellowing, vulcanization, and oxidation as in the case of a conventional silver reflective layer. Furthermore, the reflective plastic layer 140 can fill a gap between the first and second conductive lead frames 110, 120, such that a solder flux does not permeate into the gap. Therefore, the reflective plastic layer 140 can prevent shorting between the first and second conductive lead frames 110, 120.

It is to be noted that the connection relationships and materials of the elements described above will not be repeated in the following description, and only aspects related to the manufacturing processes of the light-emitting module 100 will be explained.

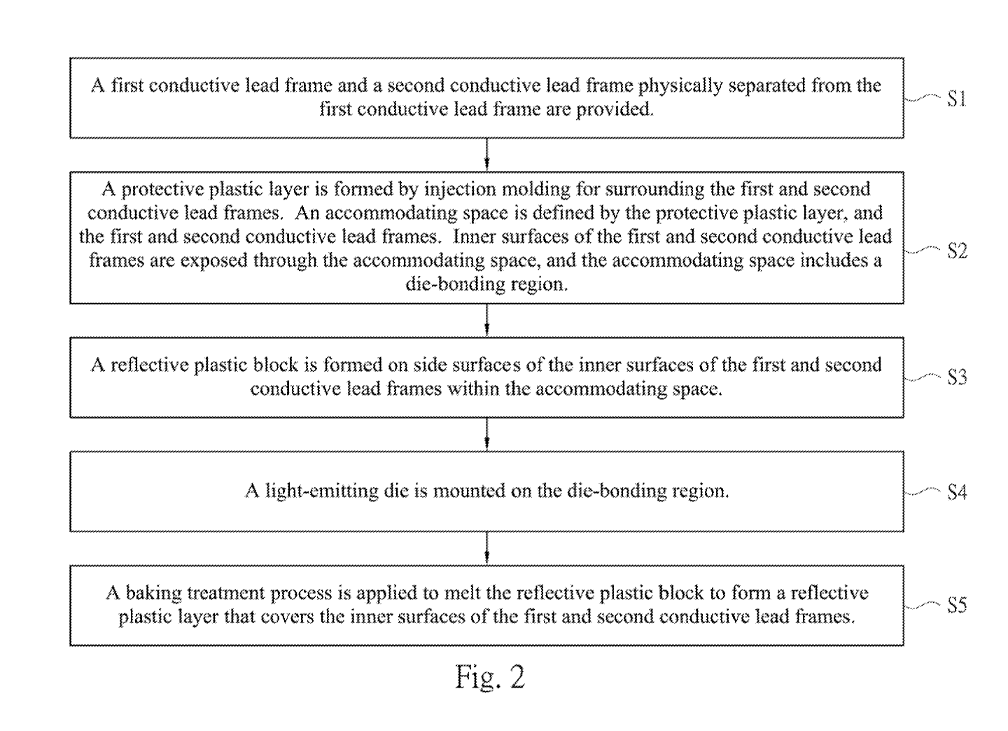

FIG. 2 is a flow chart of a manufacturing method of the light-emitting module 100 according to an embodiment of the present invention. In step S1, a first conductive lead frame and a second conductive lead frame physically separated from the first conductive lead frame are provided. Thereafter in step S2, a protective plastic layer is formed by injection molding for surrounding the first and second conductive lead frames. An accommodating space is defined by the protective plastic layer, and the first and second conductive lead frames. Inner surfaces of the first and second conductive lead frames are exposed through the accommodating space, and the accommodating space includes a die-mounting region. In step S3, a reflective plastic block is formed on side surfaces of the inner surfaces of the first and second conductive lead frames within the accommodating space. Thereafter in step S4, a light-emitting die is mounted on the die-mounting region. Finally in step S5, a baking treatment process is applied to melt the reflective plastic block to form a reflective plastic layer that covers the inner surfaces of the first and second conductive lead frames,

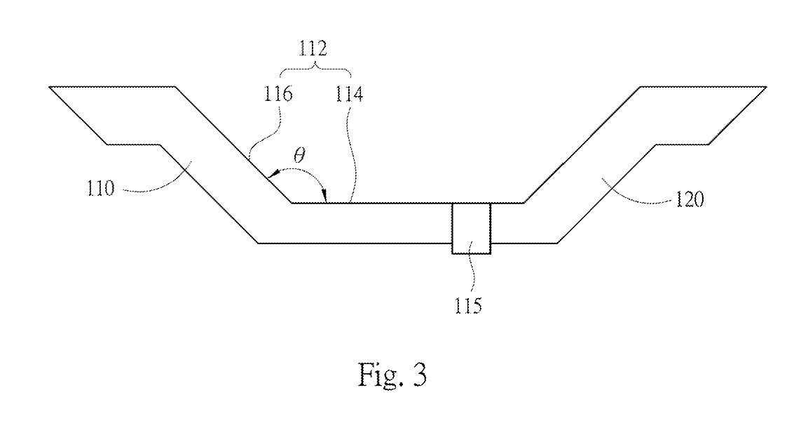

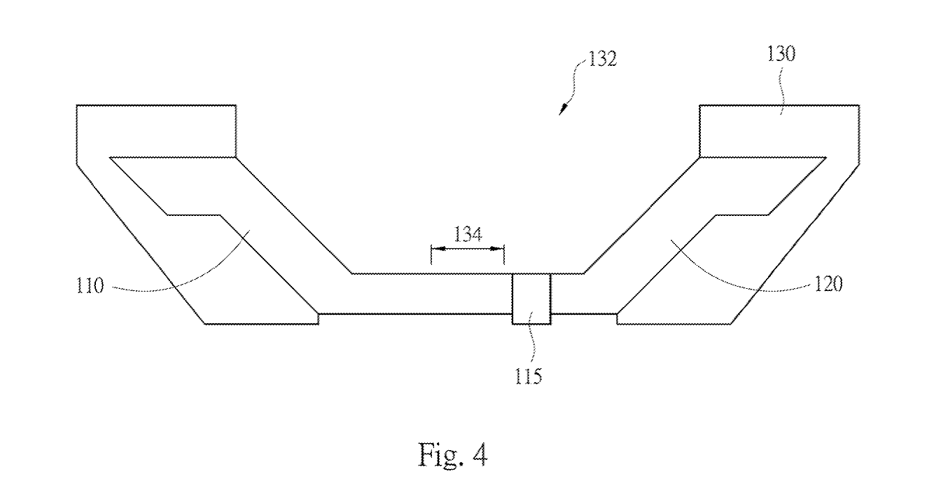

FIG. 3 is a cross-sectional view of the first and second conductive lead frames 110, 120 shown in FIG. 1. FIG. 4 is a cross-sectional view of the first and second conductive lead frames 110. 120 shown in FIG. 3 when the protective plastic layer 130 is formed thereon. As shown in FIG. 3 and FIG. 4, the second conductive lead frame 120 is physically separated from the first conductive lead frame 110. The protective plastic layer 130 may be formed by injection molding, such that the protective plastic layer 130 surrounds the outer surfaces of the first and second conductive lead frames 110, 120, and an accommodating space is defined by the protective plastic layer 130, and the first and second conductive lead frames 110, 120. The inner surfaces 112 of the first and second conductive lead frames 110, 120 are exposed through the accommodating space 132. The outer surfaces of the first and second conductive lead frames 110, 120 refer to surfaces outside of the accommodating space 132. Moreover, the accommodating space 132 further includes the die-mounting region 134 for mounting a die,

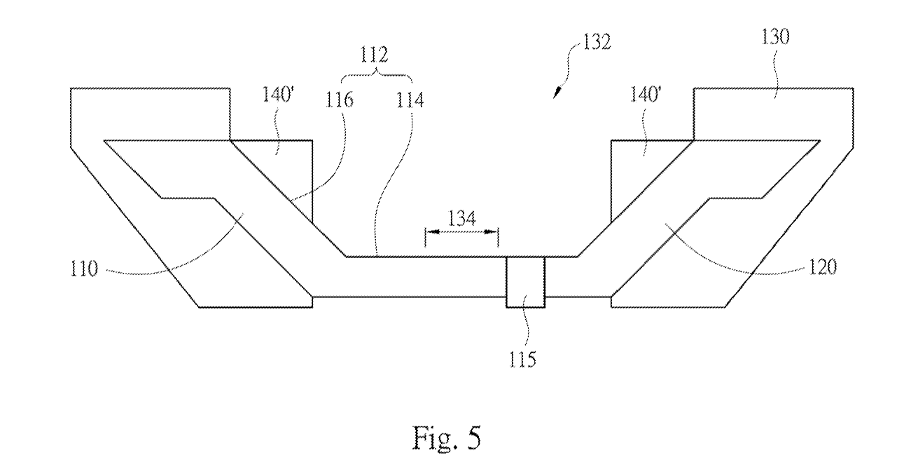

FIG. 5 is a cross-sectional view of the first and second conductive lead frames 110, 120 shown in FIG. 4 when a reflective plastic block 140′ is formed thereon. After the protective plastic layer 130 is shaped, the reflective plastic block 140′ may be formed on the side surfaces 116 of the inner surfaces 112 of the first and second conductive lead frames 110, 120.

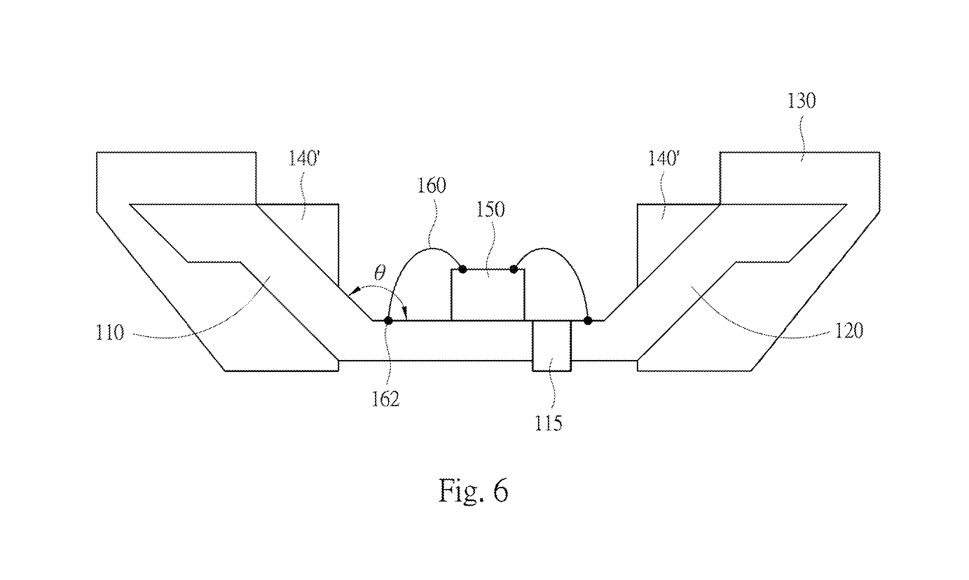

FIG. 6 is a cross-sectional view of the first and second conductive lead frames 110, 120 shown in FIG. 5 when the light-emitting die 150 is mounted thereon. After the reflective plastic block 140′ is formed on the side surfaces 116 of the inner surfaces 112 of the first and second conductive lead frames 110, 120, the light-emitting die 150 can be mounted on the die-mounting region 134, and a soldering process can be performed thereon, such that the light-emitting die 150 can be electrically connected to the first and second conductive lead frames 110, 120 by the conductive wires 160 and the solder 162.

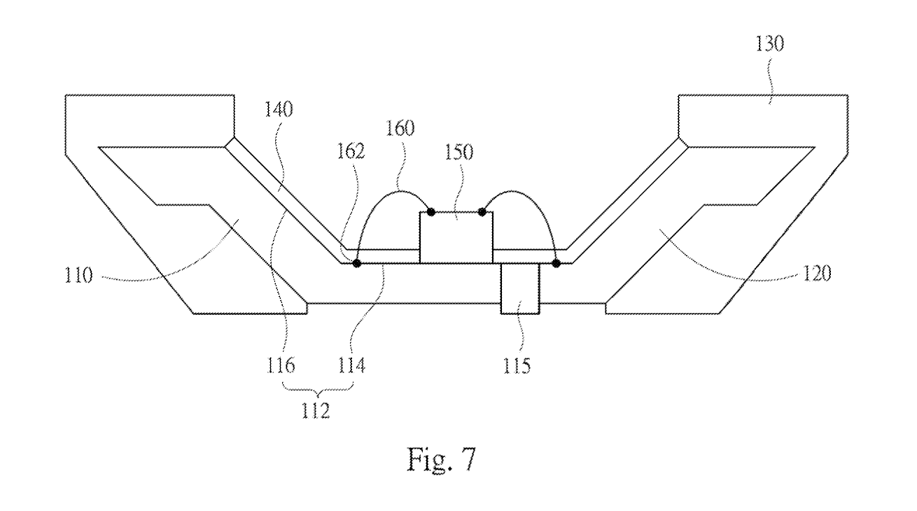

FIG. 7 is a cross-sectional view of the first and second conductive lead frames 110, 120 shown in FIG. 6 after the reflective plastic block 140′ is melted to cover the inner surfaces 112 of the first and second conductive lead frames 110, 120. As shown in FIG. 6 and FIG. 7, after the light-emitting die 150 is mounted on the first conductive lead frame 110, the structure shown in FIG. 6 can undergo a baking treatment process, such that the reflective plastic block 140′ is melted to form the reflective plastic layer 140 in a manner that covers the inner surfaces 112 of the first and second conductive lead frames 110, 120, as shown in FIG. 7. In this embodiment, the temperature of the baking treatment process is in a range from 245 to 260° C. the melting point temperature of the protective plastic layer 130 is higher than 260° C., and the melting point temperature of the reflective plastic layer 140 is lower than 245° C. As a result, during the baking treatment process, the protective plastic layer 130 remains in a solid state, while the reflective plastic block 140′ is melted into a liquid state. Since the obtuse angle θ is formed between the bottom surface 114 and the side surface 116 of the inner surface 112 of each of the first and second conductive lead frames 110, 120, the melted reflective plastic layer 140 can flow along the inner surfaces 112 of the first and second conductive lead frames 110, 120 by gravity. After the reflective plastic layer 140 is solidified by cooling, the reflective plastic layer 140 can cover the inner surfaces 112 of the first and second conductive lead frames 110, 120, as shown in FIG. 7.

The aforesaid baking treatment process may be performed in a reflow oven or in a bake chamber, but the present invention is not limited in this regard.

As shown in FIG. 1 and FIG. 7, after the reflective plastic layer 140 covers the inner surfaces 112 of the first and second conductive lead frames 110, 120, the packaging adhesive 170 can be filled in the accommodating space 132, such that the reflective plastic layer 140 and the light-emitting die 150 are covered by the packaging adhesive 170. As a result, the light-emitting module 100 shown in FIG. 1 can be realized.

Compared with the prior art, when the light-emitting die located on the die-mounting region emits light, the light of the light-emitting die can be reflected by the reflective plastic layer. Since the reflective plastic layer is made of a nonmetallic material, the reflective plastic layer does not undergo yellowing, vulcanization, and oxidation as in the case of a conventional silver reflective layer. Furthermore, the reflective plastic layer can fill a gap between the first and second conductive lead frames, such that a solder flux does not permeate into the gap. Therefore, the reflective plastic layer can prevent shorting between the first and second conductive lead frames. In addition, when baking the reflective plastic block, the protective plastic layer having a higher melting point remains in a solid state, and the reflective plastic block having a lower melting point is melted into a liquid state. Since the obtuse angle θ is formed between the bottom surface and the side surface of the inner surface of each of the first and second lead frames, the melted reflective plastic layer can flow along the inner surfaces of the first and second conductive lead frames by gravity. After the reflective plastic layer is solidified by cooling, the reflective plastic layer can cover the inner surfaces of the first and second conductive lead frames.

The reader's attention is directed to all papers and documents which are filed concurrently with this specification and which are open to public inspection with this specification, and the contents of all such papers and' documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A light-emitting module comprises:
a first conductive lead frame and a second conductive lead frame physically separated from the first conductive lead frame;
a protective plastic layer surrounding the first and second conductive lead frames, wherein an accommodating space is defined by the protective plastic layer, and the first and second conductive lead frames, and inner surfaces of the first and second conductive lead frames are exposed through the accommodating space, and the accommodating space comprises a die-mounting region;
a reflective plastic layer formed on the inner surfaces within the accommodating space; and
a light-emitting die located on the die-mounting region and respectively electrically connected to the first and second conductive lead frames, wherein the light-emitting die protrudes from the reflective plastic layer.

2. The light-emitting module of claim 1, wherein each of the inner surfaces of the first and second conductive lead frames comprises a bottom surface and a side surface, and an obtuse angle is formed between the bottom surface and the side surface.

3. The light-emitting module of claim 2, wherein the die-mounting region is on the bottom surface of the inner surface of one of the first and second conductive lead frames, and a thickness of the reflective plastic layer on the bottom surface is smaller than a thickness of the light-emitting die.

4. The light-emitting module of claim 2, wherein the obtuse angle is in range from 100 to 170 degrees.

5. The light-emitting module of claim 1, wherein the light-emitting die has at least two conductive wires, and the two conductive wires are respectively electrically connected to the first and second conductive lead frames by solder, and a melting point temperature of the reflective plastic layer is lower than a melting point temperature of the solder.

6. The light-emitting module of claim 5, wherein a melting point temperature of the protective plastic layer is higher than the melting point temperature of the solder.

7. The light-emitting module of claim 1, further comprising:
a packaging adhesive located in the accommodating space and covering the reflective plastic layer and the light-emitting die.

8. The light-emitting module of claim 7, wherein the packaging adhesive comprises fluorescent powders for changing a wavelength of a light of the light-emitting die.

9. The light-emitting module of claim 8, wherein the reflective plastic layer is made of a thermoplastic material that is selected from the group consisting of polycarbonate (PC), polyethylene (PET), polyester (PE), polybutylene terephthalate (PBT), polycycolhexaylene terephthalate (PCT), polypropene (PP), and nylon.

10. The light-emitting module of claim 8, wherein the protective plastic layer is made of a thermoplastic material that is selected from the group consisting of polycarbonate, polyethylene, polyester, polybutylene terephthalate, polycycolhexaylene terephthalate, polypropene, and nylon.

11. A manufacturing method of a light-emitting module comprising the steps of:
(a) providing a first conductive lead frame and a second conductive lead frame physically separated from the first conductive lead frame;
(b) forming a protective plastic layer by injection molding for surrounding the first and second conductive lead frames, wherein an accommodating space is defined by the protective plastic layer, and the first and second conductive lead frames, and inner surfaces of the first and second conductive lead frames are exposed through the accommodating space, and the accommodating space comprises a die-mounting region;
(c) forming a reflective plastic block on side surfaces of the inner surfaces of the first and second conductive lead frames within the accommodating space;
(d) mounting a light-emitting die on the die-mounting region; and
(e) applying a baking treatment process to melt the reflective plastic block to form a reflective plastic layer, wherein the reflective plastic layer covers the inner surfaces of the first and second conductive lead frames.

12. The manufacturing method of the light-emitting module of claim 11, wherein step (d) further comprises:
performing a soldering process, such that the light-emitting die is electrically connected to the first and second conductive lead frames.

13. The manufacturing method of the light-emitting module of claim 11, wherein step (e) is performed in a reflow oven or in a bake chamber.

14. The manufacturing method of the light-emitting module of claim 13, wherein a temperature of the baking treatment process is in a range from 245 to 260° C., a melting point temperature of the protective plastic layer is higher than 260° C. and a melting point temperature of the reflective plastic layer is lower than 245° C.

15. The manufacturing method of the light-emitting module of claim 11, further comprising:
filling a packaging adhesive in the accommodating space for covering the reflective plastic layer and the light-emitting die.

16. The manufacturing method of the light-emitting module of claim 15, wherein the packaging adhesive comprises fluorescent powders for changing a wavelength of a light of the light-emitting die.

17. The manufacturing method of the light-emitting module of claim 16, wherein the reflective plastic layer is made of a thermoplastic material that is selected from the group consisting of polycarbonate (PC), polyethylene (PET), polyester (PE), polybutylene terephthalate (PBT), polycycolhexaylene terephthalate (PCT), polypropene (PP), and nylon,

18. The manufacturing method of the light-emitting module of claim 16, wherein the protective plastic layer is made of a thermoplastic material that is selected from the group consisting of polycarbonate, polyethylene, polyester, polybutylene terephthalate, polycycolhexaylene terephthalate, polypropene, and nylon.
